(19) United States
(12) Patent Application Publication
(10) Pub. No.: US 2024/0038746 A1
(43) Pub. Date: Feb. 1, 2024

(54) Transparent display panel

(71) Applicant: ProLight Opto Technology Corporation, Taoyuan City (TW)

(72) Inventors: Chen-Lun Hsing Chen, Taoyuan City (TW); Meng-Ting Hsieh, Taoyuan City (TW); Jung-Hao Hung, Taoyuan City (TW)

(73) Assignee: ProLight Opto Technology Corporation, Taoyuan City (TW)

(21) Appl. No.: 18/143,618

(22) Filed: May 5, 2023

(30) Foreign Application Priority Data
Aug. 1, 2022 (TW) 111208242

(51) Int. Cl. H01L 25/16

(52) U.S. Cl. CPC H01L 25/167

(57) ABSTRACT

The invention provides a transparent display, which comprises a plurality of horizontal circuit layers, wherein each horizontal circuit layer extends along a horizontal direction, a plurality of vertical conductive plugs connect the horizontal circuit layers with each other, a control integrated circuit located on one of the horizontal circuit layers, and at least one light-emitting element located on another horizontal circuit layer, wherein the control integrated circuit overlaps with the at least one light-emitting element in a vertical direction.

### BACKGROUND OF THE INVENTION

### 1. Field of the Invention

This invention relates to a transparent display, in particular to a transparent display with a light-emitting element and a packaged integrated circuit arranged on a multilayer circuit layer and then laminated, which has the advantage of smaller device area.

### 2. Description of the Prior Art

With the development of display technology, in addition to ordinary displays, the industry also began to research and develop displays with light-emitting elements made on transparent substrates (such as glass), also known as transparent display panels, which have the functions of both light transmission and display. When the light-emitting element is not activated, it can be used as transparent glass, while when the light-emitting element is activated, for example, it can generate patterns on the transparent glass to display trademarks or advertisements.

FIG. 1 shows a cross-sectional structure of a conventional transparent display. As shown in FIG. 1, a packaged integrated circuit (IC) 11 is connected to a light-emitting element 10 (such as a light emitting diode, LED) as a controller, and the packaged integrated circuit 11 and the light-emitting element 10 are connected by a circuit layer 12. The above-mentioned components are placed on an opaque carrier 14 (such as a printed circuit board, PCB), and then the opaque carrier 14 is placed on a transparent substrate 16 (such as glass). In the above structure, when the number of light-emitting elements 10 is increased, the area of the opaque carrier 14 will also increase to accommodate more light-emitting elements 10. However, the area of the opaque carrier plate 14 increases, and since the area of the transparent substrate 16 (such as glass or windows) does not change, the light-transmitting area of the transparent substrate 16 will decrease, thus affecting the total light transmittance (that is, the light-transmitting area of the transparent substrate/the total area of the transparent substrate).

Therefore, a new structure is needed, which can improve the luminous efficiency of the transparent display while maintaining good light transmittance.

### SUMMARY OF THE INVENTION

This invention provides a transparent display, which comprises a plurality of horizontal circuit layers, wherein each horizontal circuit layer extends along a horizontal direction, a plurality of vertical conductive pillars connecting the horizontal circuit layers with each other, a control integrated circuit located on one of the horizontal circuit layers, and at least one light-emitting element located on the other of the horizontal circuit layers, wherein the control integrated circuit overlaps with the at least one light-emitting element in a vertical direction.

The invention is characterized in that the control integrated circuit and the light-emitting element originally located on the same layer of the transparent substrate are made into multilayer packaged light-emitting elements, wherein the control integrated circuit and the light-emitting element are respectively arranged on different layers of the multilayer structure, so that the control integrated circuit and the light-emitting element overlap each other in the vertical direction, thus greatly reducing the occupied area of the element and obviously improving the total light transmittance of the transparent display.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a cross-sectional structure of a conventional transparent display.

FIG. 2 is a sectional structure diagram of a transparent display according to a first preferred embodiment of the present invention.

FIG. 3 is a sectional structure diagram of a transparent display according to a second preferred embodiment of the present invention.

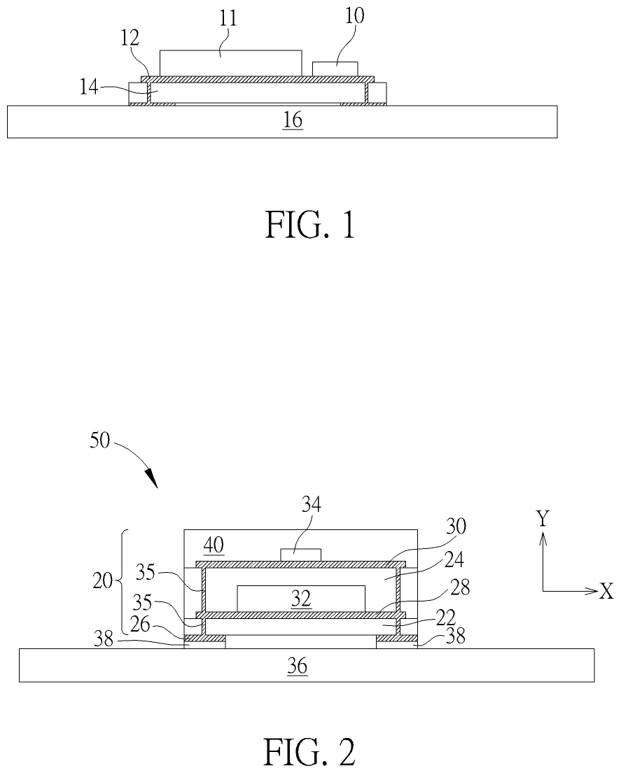

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the Figures are only for illustration and the Figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Please refer to FIG. 2, which shows a cross-sectional structural diagram of a transparent display according to a first preferred embodiment of the present invention. As shown in FIG. 2, firstly, a multi-layer packaged structure 20 is manufactured, which mainly consists of multiple material layers, multiple horizontal circuit layers, a plurality of vertical conductive pillars, a control integrated circuit and a light-emitting element. More specifically, the multilayer package structure 20 includes a first material layer 22, a second material layer 24, a first circuit layer 26, a second circuit layer 28 and a third circuit layer 30. The first material layer 22 and the second material layer 24 are made of, for example, polyimide (PI), silicone, epoxy resin, etc. The first circuit layer 26, the second circuit layer 28, and the third circuit layer 30 are made of, for example, metals with good electrical conductivity, such as copper, aluminum, tungsten, silver, gold, etc., but this invention is not limited to this. In this embodiment, the first material layer 22 is located between the first circuit layer 26 and the second circuit layer 28, and the second material layer 24 is located between the second circuit layer 28 and the third circuit layer 30. Therefore, from the cross-sectional view, the first circuit layer 26, the second circuit layer 28 and the third circuit layer 30 are located on different horizontal planes, and are separated from each other by the first material layer 22 or the second material layer 24, thus forming a multi-layer structure. It is worth noting that although this embodiment takes three circuit layers (the first circuit layer 26, the second circuit layer 28, and the third circuit layer 30) and two material layers (the first material layer 22 and the second material layer 24) as examples, in the concept of this invention, more material layers and circuit layers (for example, more than four circuit layers) can be included, which also belongs to the scope of this invention.

In addition, the multilayer package structure 20 of the present invention also includes at least one control integrated circuit (IC) 32, at least one light-emitting element 34, and a plurality of vertical conductive pillars 35. The internal structure of the control integrated circuit 32 in this embodiment is similar to that of the conventional control integrated circuit, including many logic elements such as switching elements, which can be used as a controller. The light-emitting element 34 is, for example, a light emitting diode, or further comprises an organic light emitting diode (OLED), a submillimeter light emitting diode (mini LED), a micro LED or a quantum dot LED, but it is not limited to this. The light-emitting element 34 can emit monochromatic or multi-color mixed light, such as red light, blue light, green light or other mixed light (white light, etc.) composed of multiple colors, and the present invention is not limited to this. Or in other embodiments, it may include a plurality of light-emitting elements 34, such as an LED chip composed of red, green and blue (RGB) or an LED chip composed of red, green, blue and white (RGBW), all of which are within the scope of this invention. In some embodiments, a multilayer package structure 20 can be provided with single or multiple light-emitting elements 34, and the invention does not limit the number of light-emitting elements 34 provided in a multilayer package structure 20.

In this embodiment, the control integrated circuit 32 is located on the second circuit layer 28, the light-emitting element 34 is located on the third circuit layer 30, and a plurality of vertical conductive pillars 35 penetrate through the first material layer 22 or the second material layer 24 to electrically connect the first circuit layer 26, the second circuit layer 28 and the third circuit layer 30. That is, the control integrated circuit 32 on the second circuit layer 28 and the light-emitting element 34 on the third circuit layer 30 can be electrically connected by the vertical conductive pillar 35, so that the control integrated circuit 32 can control the light-emitting element 34.

From the structure of FIG. 2, the light-emitting element 34 and the control integrated circuit 32 are located on different circuit layers, and at least partially overlap in the vertical direction. That is, compared with the prior art in which the control integrated circuit 32 and the light-emitting element 34 are arranged on the same circuit layer, the control integrated circuit 32 and the light-emitting element 34 are arranged in a stacked structure, and the light-emitting element 34 is located on the topmost circuit layer (the third circuit layer 30 in this embodiment), so that it will not be blocked by other elements to affect the light. The control integrated circuit 32 is located on the other circuit layer (the second circuit layer 28 in this embodiment) below the light-emitting element 34, so compared with the prior art, the structure of the present invention can greatly reduce the area of the device.

In addition, the control integrated circuit 32 fabricated on the second circuit layer 28 in this invention has another advantage, that is, the control integrated circuit 32 is directly contacted and covered by the second material layer 24, so that the control integrated circuit 32 can be protected by the second material layer 24, and the performance of the control integrated circuit 32 can be prevented from being affected by excessive contact with external air, moisture and oxygen. That is, the second material layer 24 can also be used as a packaging material to protect the control integrated circuit 32.

Next, a protective layer 40 is formed to cover the third circuit layer 30 and the light-emitting elements 34, wherein the protective layer 40 contains transparent insulating materials such as silicone or epoxy resin. The protective layer 40 can be used to fix the position of the light-emitting element 34, and can prevent external dust or moisture from contacting the light-emitting element 34, thus achieving the effect of protecting the element.

As shown in FIG. 2, another transparent substrate 36 is provided. The transparent substrate 36 is made of glass or other transparent materials, and a transparent conductive wire 38 made of transparent conductive materials (such as indium tin oxide, ITO) can be plated on the transparent substrate 36. The transparent substrate 36 can be used as the substrate of a transparent display, such as the transparent glass used in a window to produce a light-emitting display effect, but the invention is not limited to this. The first circuit layer 26 of the multilayer package structure 20 is used to electrically connect the transparent conductive pattern 38 on the transparent substrate 36. That is, the first circuit layer 26 directly contacts and electrically connects with the transparent conductive pattern 38.

After the above elements are formed, the transparent substrate 36, the multilayer package structure 20 and the protective layer 40 together form a transparent display 50, wherein the transparent display 50 includes the light-emitting elements 34 stacked on the control integrated circuit 32, and the multilayer package structure 20 of the transparent display 50 are directly mounted on the transparent substrate 36 including the transparent conductive pattern 38, so that the occupied area of the elements can be reduced to improve the overall light transmittance of the transparent display.

It is worth noting that in this embodiment, the first material layer 22 and the second material layer 24 can be made of hard materials such as resin, and the first circuit layer 26, the second circuit layer 28 and the third circuit layer 30 can be formed on the hard material layers such as resin by printing, so the manufactured multilayer package structure 20 can be a hard element, which is suitable for transparent substrates such as glass. On the other hand, the materials of the first material layer 22 and the second material layer 24 can also be soft materials such as silicone, so that the flexible multilayer package structure 20 can be manufactured, and then the flexible transparent display can be manufactured by matching with a flexible transparent substrate (such as a plastic film). This structure also belongs to the scope of this creation.

In addition, in the transparent display 50 of the present invention, except that the multilayer package structure 20 can be made of opaque materials, the remaining substrates (that is, the transparent substrate 36) are all made of transparent materials, so the transparent visual effect can be achieved. Different from the general display, the transparent display 50 of the present invention does not contain other opaque substrates except the above-mentioned multilayer package structure 20. That is, except for the elements on the multilayer package structure 20, the rest of the substrates used to support the elements are transparent. In addition, the total area of all multilayer package structure 20 is smaller than the area of the transparent substrate 36, and the ratio of the total area of all multilayer package structure 20 to the area of the transparent substrate 36 is preferably smaller than 0.5, but it is not limited to this.

The following description will detail the different embodiments of the transparent display panel of the present invention. To simplify the description, the following description will detail the dissimilarities among the different embodiments and the identical features will not be redundantly described. In order to compare the differences between the embodiments easily, the identical components in each of the following embodiments are marked with identical symbols.

In the above embodiment, the control integrated circuit 32 directly contacts the second circuit layer 28, and the light-emitting element 34 directly contacts the third circuit layer 30, so there is no need to form additional wires to connect the control integrated circuit 32 and the light-emitting element 34. However, in the above embodiment, the pins of the control integrated circuit 32 and the light-emitting element 34 must match the patterns of the second circuit layer 28 or the third circuit layer 30.

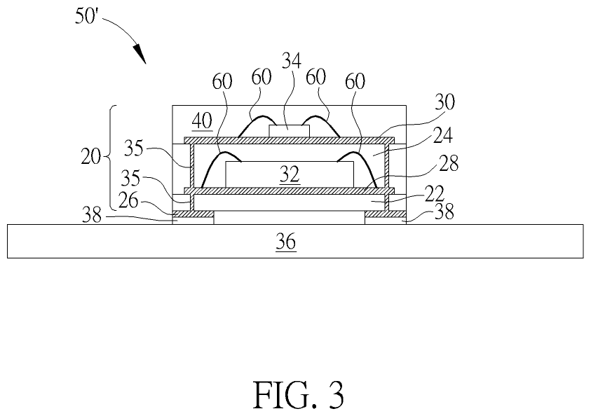

In other embodiments of this invention, wires can also be arranged according to requirements to connect the packaged integrated circuit with the light-emitting element, so that the device arrangement is more flexible. Please refer to FIG. 3, which shows a cross-sectional structural diagram of a transparent display according to a second preferred embodiment of the present invention. As shown in FIG. 3, the structure of the transparent display 50′ shown in this embodiment is similar to that of the above-mentioned first embodiment, and it also includes a transparent substrate 36, on which transparent conductive pattern 38 are included. The multilayer package structure 20 is located on the transparent substrate 36, and the first circuit layer 26 is electrically connected to the transparent conductive pattern 38. In addition, the multilayer package structure 20 also includes a plurality of material layers (the first material layer 22, the second material layer 24) and a plurality of circuit layers (the first circuit layer 26, the second circuit layer 28 and the third circuit layer 30), and the control integrated circuit 32 and the light-emitting element 34 are located on different circuit layers, and are electrically connected with each other by vertical conductive pillars 35. It is worth noting that the control integrated circuit 32 in this embodiment is also located on the second circuit layer 28, and the light-emitting element 34 is also located on the third circuit layer 30, but this embodiment further includes a plurality of metal wires wherein the metal wires 60 can be used to connect the control integrated circuit 32 with the second circuit layer 28 or electrically connect the light-emitting element 34 with the third circuit layer 30. Therefore, if the pins of the control integrated circuit 32 and the light-emitting element 34 do not match the patterns of the second circuit layer 28 or the third circuit layer 30, the metal wires can make up for it. The advantage of this embodiment is that the flexibility of the arrangement of the light-emitting elements 34 can be improved.

Based on the above description and drawings, this invention provides a transparent display, which includes a plurality of horizontal circuit layers (the first circuit layer 26, the second circuit layer 28 and the third circuit layer 30), wherein each horizontal circuit layer extends in a horizontal direction (for example, along the X direction in FIG. 2), a plurality of vertical conductive pillars 35, a control integrated circuit 32 disposed on one of the horizontal circuit layers (e.g., the second circuit layer 28), and at least one light-emitting element 34 on the other of the horizontal circuit layers (e.g., the third circuit layer 30), wherein the control integrated circuit 32 and the at least one light-emitting element 34 overlap in a vertical direction (e.g., in the Y direction of FIG. 2).

In some embodiments of the present invention, the multi-layer horizontal circuit layer includes a first circuit layer 26, a second circuit layer 28 and a third circuit layer 30, wherein the control integrated circuit 32 is located on the second circuit layer 28 and the light-emitting element 34 is located on the third circuit layer 30.

In some embodiments of the present invention, a transparent substrate 36 is further included, and a transparent conductive pattern 38 is included on the transparent substrate, wherein the first circuit layer 26 is electrically connected with the transparent conductive pattern 38.

In some embodiments of the present invention, the transparent substrate 36 is made of glass, and the transparent conductive pattern 38 is made of indium tin oxide (ITO).

In some embodiments of the present invention, an area of each horizontal circuit layer (the first circuit layer 26, the second circuit layer 28 and the third circuit layer 30) is smaller than an area of the transparent substrate 36.

In some embodiments of the present invention, except the transparent substrate 36, the transparent displays 50, 50′ do not contain other substrates made of transparent materials.

In some embodiments of this invention, a first material layer 22 is further included, wherein the first material layer 22 is located between the first circuit layer 26 and the second circuit layer 28, and part of the vertical conductive pillars 35 penetrate through the first material layer 22 and electrically connect the first circuit layer 26 and the second circuit layer 28.

In some embodiments of this invention, a second material layer 24 is further included, wherein the second material layer 24 is located between the second circuit layer 28 and the third circuit layer 30, and part of the vertical conductive pillars 35 penetrate through the second material layer 24 and electrically connect the second circuit layer 28 and the third circuit layer 30.

In some embodiments of the present invention, the control integrated circuit 32 directly contacts the second material layer 24 and the second circuit layer 28.

In some embodiments of the present invention, a protective layer 40 is further included to cover the light-emitting element 34.

In some embodiments of the present invention, the protective layer 40 is made of transparent silicone or epoxy resin.

In some embodiments of the present invention, it further includes a plurality of metal wires 60, which electrically connect the light-emitting element 34 with the third circuit layer 30, or electrically connect the control integrated circuit 32 with the second circuit layer 28.

The invention is characterized in that the control integrated circuit and the light-emitting element originally located on the same layer of the transparent substrate are made into multilayer packaged light-emitting elements, wherein the control integrated circuit and the light-emitting element are respectively arranged on different layers of the multilayer structure, so that the control integrated circuit and the light-emitting element overlap each other in the vertical direction, thus greatly reducing the occupied area of the element and obviously improving the total light transmittance of the transparent display.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transparent display comprising:
a plurality of horizontal circuit layers, wherein each horizontal circuit layer extends along a horizontal direction;
a plurality of vertical conductive pillars connecting the horizontal circuit layers to each other;
a control integrated circuit located on one of the horizontal circuit layers; and
at least one light-emitting element located on the other layer of the horizontal circuit layers, wherein the control integrated circuit and the at least one light-emitting element overlap in a vertical direction.

2. The transparent display of claim 1, wherein the plurality of horizontal circuit layer comprises a first circuit layer, a second circuit layer and a third circuit layer, wherein the control integrated circuit is located on the second circuit layer and the light-emitting element is located on the third circuit layer.

3. The transparent display of claim 2, further comprising a transparent substrate and a transparent conductive pattern disposed thereon, wherein the first circuit layer is electrically connected with the transparent conductive pattern.

4. The transparent display of claim 3, wherein the transparent substrate is made of glass, and the transparent conductive pattern is made of indium tin oxide (ITO).

5. The transparent display of claim 3, wherein an area of each horizontal circuit layer is smaller than an area of the transparent substrate.

6. The transparent display of claim 3, wherein the transparent display does not contain other substrates made of transparent materials except the transparent substrate.

7. The transparent display of claim 2, further comprising a first material layer, wherein the first material layer is located between the first circuit layer and the second circuit layer, and part of the vertical conductive pillars penetrate through the first material layer and electrically connect the first circuit layer and the second circuit layer.

8. The transparent display of claim 2, further comprising a second material layer, wherein the second material layer is located between the second circuit layer and the third circuit layer, and part of the vertical conductive pillars penetrate through the second material layer and electrically connect the second circuit layer and the third circuit layer.

9. The transparent display of claim 8, wherein the control integrated circuit directly contacts the second material layer and the second circuit layer.

10. The transparent display of claim 1, further comprising a protective layer covering the light-emitting element.

11. The transparent display of claim 10, wherein the protective layer is made of transparent silicone or epoxy resin.

12. The transparent display of claim 1, further comprising a plurality of metal wires electrically connecting the light-emitting element with the third circuit layer or electrically connecting the control integrated circuit with the second circuit layer.
